(19) United States
(12) Patent Application Publication
(10) Pub. No.: US 2018/0233695 A1
(43) Pub. Date: Aug. 16, 2018

(54) DISPLAY MODULE

(71) Applicant: Wuhan China Star Optoelectronics Technology Co., Ltd., Wuhan, Hubei (CN)

(72) Inventors: Szu Yuan WANG, Shenzhen, Guangdong (CN); Lei HU, Shenzhen, Guangdong (CN)

(73) Assignee: Wuhan China Star Optoelectronics Technology Co., Ltd., Wuhan, Hubei (CN)

(21) Appl. No.: 15/510,670

(22) PCT Filed: Feb. 14, 2017
(86) PCT No.: PCT/CN2017/073528

§ 371 Date: Mar. 10, 2017

(30) Foreign Application Priority Data
Jan. 20, 2017 (CN) 201710051857.X

(51) Int. Cl. H01L 51/52; H01L 51/00

(52) U.S. Cl. CPC H01L 51/5237; H01L 51/5221; H01L 2251/5338; H01L 51/5206; H01L 51/0097

(57) ABSTRACT

This disclosure is related to display technology field, especially one kind of display module, which comprises a middle frame and a flexible display panel arranged on the middle frame, and the middle frame is provided with a first magnetic piece. The flexible display panel comprises a substrate, and the substrate was provided with a second magnetic piece corresponding to the first magnetic piece, so that the flexible display panel is cooperatively connected with the middle frame by the first magnetic piece and the second magnetic piece. This disclosure is suitable for a bending operation of the flexible display panel by using the magnetic material, reduces the stress generated by the middle frame and the adhesive on the flexible display panel. The display panel can be repeatedly reworked without damaging the performance of the display panel. The workload is reduced with increasing the working efficiency, and reducing the production cost.

### TECHNICAL FIELD

This disclosure belongs to LCD technology, especially is related to one kind of assembly method of a flexible display panel.

### DESCRIPTION OF RELATED ART

With the development of Organic Light-Emitting Diode (OLED) display technology has matured, consumers have experienced the extremely difference between OLED and LCD display, the increasing growing of OLED consumption market has followed. Due to self-luminous characteristics of OLED, these features such as short response time, high ratio, wide color gamut, light and thin display panel, and flexibility can be achieved. Especially the bending of OLED display panel, it brings a disruptive concept to consumers, so that Flexible OLED becomes mainstream in recent years.

Then, the bendable display panel also becomes a challenge to the device assembly of the electronic equipment. The traditional final vendors often use the paste method to stick the display panel on the middle frame. For glass substrate display panel, using this method to fix is better due to the rigidity of glass substrate. However, for a flexible OLED display panel, the assembly method by using middle frame with adhesive to fix would generate the stress to the flexible display panel during the bending process and easily damage the flexible display panel to greatly reduce the bending reliability of products.

Meanwhile, when fixing the display panel that is very flexible, using this method often causes imprecise paste location and brings rework, difficulty to fix due to the substrate itself being flexible, which causes the problem of reducing yield rate, affects production efficiency and increase production cost.

People wish to find a new fix method applied for flexible display panel.

### SUMMARY

To solve the above-mentioned problem that prior art exists, this disclosure offers a kind of new display module, which comprises a middle frame and a flexible display panel arranged on the middle frame, and the middle frame is provided with a first magnetic piece.

The flexible display panel comprises a substrate, and the substrate was provided with a second magnetic piece corresponding to the first magnetic piece. The flexible display panel is cooperatively connected with the middle frame by the first magnetic piece and the second magnetic piece.

The middle frame comprises the first rectangular portion and the second rectangular portion, and the rotating assembly between the first rectangular portion and the second rectangular portion. The first rectangular portion and the second rectangular portion rotate around the rotating assembly relatively. The middle frame at least has folded state and flattened state.

The first rectangular portion and the second rectangular portion corresponding to the display panel are all provided with a supporting groove for supporting the display panel. The first magnetic piece is arranged on the supporting groove.

The rotating assembly comprises at least two hinges and a rotating axis arranged between the two hinges. The hinges are arranged between side surface of the first rectangular portion and the second rectangular portion.

The first magnetic piece is integrated into the middle frame.

Wherein the flexible display panel comprises a cathode layer, an electron transporting layer, an organic emitter, a hole injection layer, an anode layer, and a protective layer arranged sequentially on the substrate from bottom to top.

The second magnetic piece is integrated into the substrate.

### Beneficial Effects

By using the magnetic fixing method, this disclosure does not need the adhesive to stick the flexible display panel to middle frame, satisfies the needs of final vendor. Meanwhile, due to the use of the magnetic material, this disclosure is suitable for a bending operation of the flexible display panel, reduces the stress generated by the middle frame and the adhesive on the flexible display panel, and can repeatedly rework without damage the performance of the display panel, reduce the workload, increase the working efficiency, and reduce the production cost.

### BRIEF DESCRIPTION

The following description taken in conjunction with the above and other aspects, features and advantages of the embodiments of the present disclosure will become more apparent from the accompanying drawings in which:

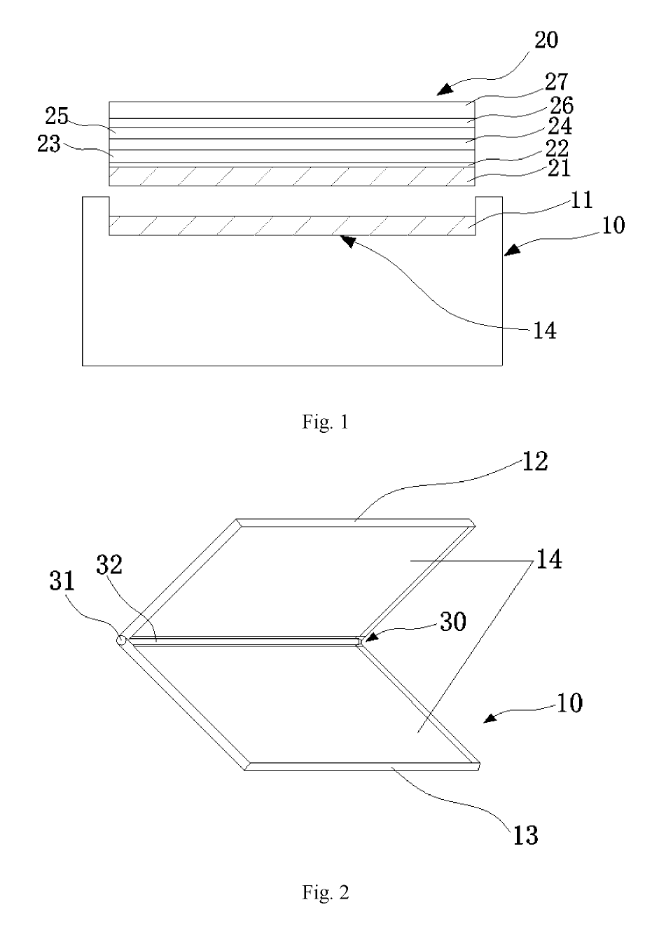

FIG. 1 is a schematic view of the structure of the present disclosure during the display panel and middle frame laminating process.

FIG. 2 is a schematic view of the structure of the middle frame of the present disclosure.

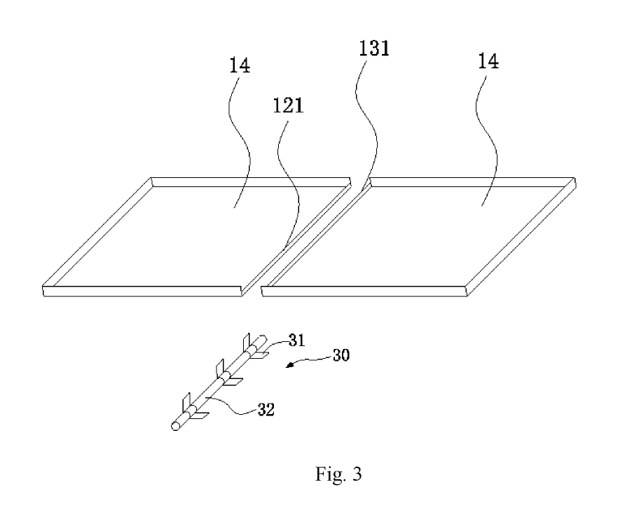

FIG. 3 is an exploded view of the structure of the middle frame of the present disclosure.

### DETAILED DESCRIPTION OF EMBODIMENTS

Hereinafter, embodiments of the present disclosure will be described in detail with reference to the accompanying drawings. However, the present disclosure can be embodied in many different forms, and the disclosure should not be construed as limited to the specific embodiments set forth herein. Rather, these embodiments are provided to explain the principles of the disclosure and its practical application so that others skilled in the art to understand the disclosure for various embodiments and various modifications suited to the particular intended application.

The present disclosure provides a display module, shown in FIG. 1, which comprises the middle frame 10, and the flexible display panel 20 installed in of the middle frame. The flexible display panel of the present disclosure uses a flexible OLED display panel for example.

The flexible display panel 20 comprises the cathode layer 22, the electron transport layer 23, an organic transmitter 24, a hole injection layer 25, an anode layer 26 and a protective layer 27, which are arranged on the substrate 21 from bottom to top. In general, the substrate 21 and the protection layer 27 are plastic materials.

Shown in conjunction with FIG. 2, on the middle frame 10, corresponding to the side of display panel 20, the first magnetic piece 11 is provided. The substrate 21 is provided with the first magnetic piece 11 corresponding to the second magnetic piece, so that the flexible display panel 20 is cooperative connected with the middle frame 10 by the first magnetic piece 11 and the second magnetic piece. In this embodiment, the second magnetic piece 21 is preferably formed integrally with the substrate 21, namely the magnetic material is directly introduced during the manufacturing process of the substrate 21, so that the entire substrate itself is magnetic. In other words, the substrate can be considered as the second magnetic piece. In other embodiments, the second magnetic piece can also be combined with the substrate by the paste method.

To cope with the flexible display panel bendable performance, the middle frame can also be produced as bendable structure. As shown in FIGS. 2 and 3, the middle frame 10 of the present disclosure comprises the first rectangular portion 12, and the second rectangular portion 13, and the rotating assembly 30 which is connected between the first rectangular portion 12, and the second rectangular portion 13. The first rectangular portion 12 and the second rectangular portion 13 rotate relatively around the rotating assembly 30, so that the middle frame 10 has at least folded state and flattened state.

Further, the first rectangular portion 12 and the second rectangular portion 13 corresponding to the flexible display panel 20 both have a supporting groove 14 for supporting the flexible display panel 20, the first magnetic piece 11 is arranged on the supporting groove 14. Specifically, the first magnetic piece 11 can be assembled on the supporting groove 14 by the paste method, or the magnetic materials can be induced directly into the production materials of the middle frame to integrated into the middle frame, makes the whole middle frame all with magnetic.

In conjunction with FIG. 3, the rotating assembly 30 comprises at least two hinge elements 31 and the rotary axis 32 arranged between the two hinges 31: when the middle frame 10 is in flat state, the first rectangular portion 12 and the second rectangular portion 13 have the adjacent side surfaces 121 and 131. the hinge elements 31 are between the adjacent side surfaces 121 and 131 of the first rectangular portion 12 and the second rectangular portion 13. The first rectangular portion 12 and the second rectangular portion 13 rotate around the rotating axis 32 and can be at any angle to the angle between the plane 13, so that the middle frame can at least has folded state and flattened state, and can also be expanded like “wings” at any angle to satisfy the requirements of the flexible display panel.

When assembling, the middle frame 10 is expanded flatly, and then the flexible display panel 20 is placed in the default installing position within the middle frame 10, the flexible display panel 20 is provided with the second magnetic piece 21 and corresponds to the middle frame 11 provided with the first magnetic piece 11, both of which attract each other, the assembling is completed. Since the display panel and the middle frame are fixed only by magnetic attraction, even when the assembling is not precise, they can be disassembly separated infinitely and be reassembled without affecting the performance of flexible display panel; moreover, when the flexible display panel is bended, the magnetic attraction method, different from the adhesive, allows the contact surfaces of the flexible display panel and the middle frame to produce relative displacement to reduce the damage of stress to the flexible panel. When the flexible display panel is flat, the display panel would be bonded with the middle frame by magnetic attraction to maintain a good fixed structure.

By using the magnetic fixing method, this disclosure does not need the adhesive to stick the flexible display panel to the middle frame, satisfies the needs of final vendor. Meanwhile, due to the use of the magnetic material, this disclosure is suitable for a bending operation of the flexible display panel, reduces the stress generated by the middle frame and the adhesive, and reduces the workload, improves work efficiency, and reduces production costs.

Although reference to particular embodiments shown and described the present disclosure, those skilled in the art will understand: without departing from the spirit and scope of the appended claims and their equivalents of the present disclosure, the case can be carried out in this form and various changes in detail.

What is claimed is:

1. A display module, comprising:
a middle frame and a flexible display panel arranged on the middle frame, and the middle frame is provided with a first magnetic piece; the flexible display panel comprises a substrate, and the substrate was provided with a second magnetic piece corresponding to the first magnetic piece; the flexible display panel is cooperatively connected with the middle frame by the first magnetic piece and the second magnetic piece.

2. The display module according to claim 1, wherein the middle frame comprises a first rectangular portion and a second rectangular portion, and a rotating assembly between the first rectangular portion and the second rectangular portion; the first rectangular portion and the second rectangular portion rotating around the rotating assembly relatively, such that the middle frame at least has folded state and flattened state.

3. The display module according to claim 2, wherein the first rectangular portion and the second rectangular portion corresponding to the flexible display panel both have a supporting groove for supporting the flexible display panel, the first magnetic piece is arranged on the supporting groove.

4. The display module according to claim 3, wherein the rotating assembly comprises at least two hinges and a rotating axis arranged between the two hinges, the hinges are arranged between side surface of the first rectangular portion and the second rectangular portion.

5. The display module according to claim 1, wherein the first magnetic piece is integrated into the middle frame.

6. The display module according to claim 1, wherein the flexible display panel comprises a cathode layer, an electron transporting layer, an organic emitter, a hole injection layer, an anode layer, and a protective layer arranged sequentially on the substrate from bottom to top.

7. The display module according to claim 1, wherein the second magnetic piece is integrated into the substrate.

8. The display module according to claim 6, wherein the second magnetic piece is integrated into the substrate.
